(19) United States
(12) Patent Application Publication
(10) Pub. No.: US 2007/0035983 A1
(43) Pub. Date: Feb. 15, 2007

(54) Ferroelectric random access memory device and method for controlling writing sections therefor

(75) Inventors: Kang-Woon Lee, Seoul (KR); Byung-Jun Min, Yongin-si (KR); Han-Joo Lee, Seoul (KR); Byung-Gil Jeon, Suwon-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/484,280

(22) Filed: Jul. 11, 2006

(30) Foreign Application Priority Data
Jul. 13, 2005 (KR) 2005-63181

(51) Int. Cl. G11C 11/22

(52) U.S. Cl. 365/145

(57) ABSTRACT

A FeRAM device and a writing section control method therefor, in which the device includes a memory cell constructed of one access transistor and one ferroelectric capacitor; and a writing control circuit for controlling a first writing section to write data of a first logic state in the memory cell and a second writing section to write data of a second logic state different from the first logic state, in response to an external clock signal. Thus a stabilized write operation can be performed and a reliability of data stored in the memory cell can be tested.

### CROSS-REFERENCE TO RELATED APPLICATIONS

This application relies for priority upon Korean Patent Application No. 2005-63181 filed on Jul. 13, 2005, the contents of which are herein incorporated by reference in its entirety.

### TECHNICAL FIELD

The present disclosure relates to a ferroelectric memory device and a writing section control method therefor, through which a stabilized write operation can be performed.

### BACKGROUND DISCUSSION

Recently devices to overcome limitations on a refresh capability necessary for a DRAM(Dynamic Random Access Memory) device with a large capacity of memory have been developed by using a ferroelectric thin film for the dielectric film of a capacitor. A ferroelectric random access memory (FRAM or FeRAM) using such ferroelectric thin film is a kind of nonvolatile memorydevice and has the merits of remembering storage information in a power-off state and of a high-speed access, and of a low power consumption and an endurance from impact. It is expected to use the FeRAM as a main memory part in various kinds of electronic equipment having file storage and search functions, such as portable computers, cellular phones and game machines etc., or as a record medium for recording voice or images.

In the FeRAM, a memory cell constructed of a ferroelectric capacitor and an access transistor stores data as ‘1’ or ‘0’ based on an electric polarization state of a ferroelectric capacitor.

FIG. 1 illustrates a hysteresis curve of general ferroelectric material constituting a ferroelectric memory cell. In the hysteresis curve, the X-axis indicates a voltage applied to both ends of a capacitor, as voltage applied to the ferroelectric material, with the assumption that an electrode of the side connected to a plate line is a positive electrode and an electrode of another side is a negative electrode among the two electrodes of the ferroelectric capacitor; and a Y-axis indicates the volume of charge excited to the surface by a spontaneous polarization of the ferroelectric material, that is, a polarization level μC/cm².

Referring to FIG. 1, when a voltage of ground level Vss or 0V is applied and no electric field is applied to the ferroelectric material, polarization is not generated. When the voltage of both ends of a ferroelectric capacitor increases in a plus direction, a polarization level or charge amount increases from zero to a state point A of a plus polarization region. At the state point A, a polarization is generated in one direction, and a polarization level of the state point A has a greatest value. At this time, the polarization level, which is the charge amount that the ferroelectric material retains, is represented as +Qs. Then, even though the voltage of both ends of the capacitor falls to ground voltage Vss, a polarization level does not fall to zero but falls to and remains at a state point B. The charge amount that the ferroelectric material retains by such remaining polarization, which is a residual polarization level, is represented as +Qr. Then, when the voltage of both ends of the capacitor increases in a negative direction, a polarization level is changed to a state point C of a negative charge polarization region from the state point B. At the state point C, the ferroelectric material is polarized to a direction opposite to the polarization direction of the state point A. At this time, the polarization level is represented as −Qs. Then, even though voltage of both ends of the capacitor again returns to a ground voltage Vss, a polarization level does not return to zero but remains at a state point D. At this time, a residual polarization level is represented as −Qr. When voltage applied to both ends of the capacitor again increases in a plus direction, a polarization level of the ferroelectric material is changed to the state point A from the state point D.

When the voltage to generate an electric field is once applied to a ferroelectric capacitor formed of ferroelectric material inserted between two electrodes, and then, even though the electrodes are determined as a floating state, a polarization direction based on a spontaneous polarization is maintained. Furthermore, surface charge of the ferroelectric material through the spontaneous polarization is not lost naturally by leakage, etc. If the voltage is not applied in an opposite direction so that the polarization level becomes zero, a polarization direction is maintained intact.

When a voltage is applied in a plus direction to the ferroelectric capacitor and then removed, residual polarization of the ferroelectric material constituting the ferroelectric capacitor becomes a state of +Qr. When a voltage is applied in a negative direction to the ferroelectric capacitor and then removed, residual polarization of the ferroelectric material becomes a state of −Qr. At this time, assuming that a logic state indicates data ‘0’ when the residual polarization has a state of +Qr; when residual polarization has a state of −Qr, a logic state indicates data ‘1’.

FIG. 2 illustrates a memory cell of a memory cell array in a general FeRAM.

With reference to FIG. 2, a memory cell is constructed of one access transistor M1 and one ferroelectric capacitor C_{FE}. The access transistor M1 has two terminals, a source terminal and a drain terminal, which are respectively connected between one electrode of the ferroelectric capacitor C_{FE} and a bit line B/L, and a gate of the access transistor M1 is connected to a word line W/L. One electrode of the ferroelectric capacitor C_{FE} is coupled with the drain terminal of the access transistor M1, and another electrode thereof is coupled with a plate line P/L.

In a FeRAM having cell arrays such that the memory cells are arrayed in a plurality of rows and columns, a read or write operation is performed by a pulse applied to the ferroelectric memory cell. The write operation is performed depending upon a state of data applied to the bit line B/L and a plate control signal is applied to the plate line P/L.

In a general FeRAM, a section of writing data ‘0’ is separated from a section of writing data ‘1’ in one cycle, to obtain a stabilized write operation. Generally, the section of writing data ‘0’ is first determined and then the section of writing data ‘1’ is determined.

FIG. 3 illustrates a timing diagram of the write operation in a FeRAM according to a prior art.

As shown in FIG. 3, in the state that an external chip enable signal XCEB is maintained as an enable state in a low level, an address signal XADD is applied from the outside. A specific memory cell to be written is selected in response to the address signal XADD. A word line W/L of the specific memory cell is enabled by a word line decoder and driver circuit that responds to the address signal XADD.

The plate line P/L is enabled by a plate control signal generated in a plate line driver circuit responding to the address signal XADD. When the plate line P/L is enabled, a reading section starts. When the plate line P/L is enabled and the reading section starts, a voltage corresponding to data stored in the selected memory cell is developed to a bit line B/L maintained at ground voltage.

Then, the plate line P/L is enabled, and after a given delay, a sense amplifier enable signal SAEN to operate a sense amplifier within the FeRAM is enabled, and so the sense amplifier is enabled. When the sense amplifier is enabled, the reading section is finished.

Subsequently, the data writing section is divided into a writing section t1 of data ‘0’ and a writing section t2 of data ‘1’ by an enable or disable state of the plate line P/L. That is, a section from an enabled time point of the sense amplifier enable signal SAEN to a disabled time point of the plate line P/L, is the writing section t1 of data ‘0’, and a section from the disabled time point of the plate line P/L to a disabled time point of the sense amplifier enable signal SAEN, is the writing section t2 of data ‘1’.

In the writing section t1 of data ‘0’, the write operation is generated when a state of data applied through the bit line B/L from the outside is ‘0’. In other words, when data inputted from the outside is ‘0’, a voltage of the bit line B/L maintains a ground level, and the data ‘0’ is written by a voltage level difference from the plate line P/L having an enable state of a power source voltage level.

On the other hand, when data applied through the bit line B/L is ‘1’, a voltage of the bit line B/L maintains a level of a power source voltage, and there is no voltage difference from the plate line P/L having an enable state, thus no operation occurs. The write operation of data ‘0’ is performed after a given lapse of time after the sense amplifier enable signal SAEN is enabled, and before the plate line P/L is disabled.

Subsequently, at the writing section t2 of data ‘1’, the write operation is generated when a state of data applied through the bit line B/L from the outside is ‘1’. In other words, when data inputted from the outside is ‘1’, a voltage of the bit line B/L maintains a level of the power source voltage, and the data ‘1’ is written by a voltage level difference from the plate line P/L having a disable state at a ground level.

When data applied through the bit line B/L is ‘0’, a voltage of the bit line B/L maintains a ground level, and there is not a voltage difference from the plate line P/L having a disable state, thus no any operation occurs. The write operation of data ‘1’ continues until the sense amplifier enable signal SAEN is disabled. The sense amplifier enable signal SAEN is disabled at a time point when the external address signal XADD of the next cycle is applied.

When the write operation is completed, the bit line B/L is precharged, and the word line W/L is disabled.

In a FeRAM performing such write operation, the sense amplifier enable signal SAEN is controlled to be enabled after the plate line P/L is enabled and a time corresponding to a reading section lapses. After the sense amplifier enable signal SAEN is enabled and the time corresponding to the writing section t1 of data ‘0’ lapses, the plate line P/L is controlled to be disabled. The sense amplifier is controlled to be disabled, after the plate line P/L is disabled and after a time corresponding to a writing section t2 of data ‘1’ lapses.

In the conventional FeRAM, the writing section t1 of data ‘0’ is fixed, and the writing section t2 of data ‘1’ is variable by a cycle time. The writing section t1 of data ‘0’ is a time interval from an enabled time point of the sense amplifier enable signal SAEN to a disabled time point of the plate line P/L after a lapse of a fixed delay time determined in a delay circuit. Thus, the writing section t1 of data ‘0’ is a time interval corresponding to the fixed delay time of the delay circuit, regardless of a change of cycle time. However, the writing section of data ‘1’ is a time interval from a disabled time point of the plate line P/L to a disabled time point of sense amplifier enable signal SAEN after one cycle is completed, and this time interval may become lengthened or shortened variably based on the cycle time.

In particular, in case the cycle time is long, a difference between the writing section of data ‘0’ and the writing section of data ‘1’ becomes great, in other words, an unbalanced writing may be caused, and a difference in sensing margin and reliability of data ‘0’ and data ‘1’ may result. When a writing section of data ‘0’ is not sufficient to fall within a prediction error for a loading of enabled or disabled plate line, failure may result. Such conventional FeRAM impedes a stabilized write operation, due to problems that the loading prediction error of the plate line is caused when a cycle time is too long, for example.

### SUMMARY OF THE INVENTION

An exemplary embodiment of the present invention provides a ferroelectric random access memory(FeRAM) device and a method of controlling a writing section thereof, in which a stabilized write operation can be performed. A data writing section can be controlled by controlling a cycle time, and the reliability of data written and stored in memory cells can be checked by testing.

According to an embodiment of the present invention, a FeRAM device comprises a memory cell constructed of one access transistor and one ferroelectric capacitor; and a writing control circuit for controlling a first writing section to write data of a first logic state in the memory cell and a second writing section to write data of a second logic state different from the first logic state, in response to an external clock signal.

A time point that is changed from the first writing section to the second writing section may be a lapse time point of a half-cycle of the external clock signal. The writing control circuit can control the first writing section and the second writing section by controlling a level of the plate control signal applied to the plate line. The first writing section is a section in which the plate control signal has a first level state, and the second writing section is a section in which the plate control signal has a second level state different from the first level state. The FeRAM device may be a synchronous ferroelectric memory device operating synchronously in relation to the external clock signal. When the FeRAM is an asynchronous semiconductor memory device, the external clock signal can be applied through a specific test pin.

According to an embodiment of the present invention, a FeRAM device comprises a memory cell constructed of one access transistor and one ferroelectric capacitor; and a writing control circuit for controlling a level state of the plate control signal applied to a plate line connected to the memory cell in response to first and second control signals inputted from the outside, so as to write in the memory cell data that is applied through a bit line.

The first control signal may be an external clock signal, and the second control signal may be a sense amplifier enable signal to enable a sense amplifier provided with the FeRAM device. The FeRAM device may be a synchronous FeRAM operating synchronously in relation to the external clock signal, and the writing control circuit can be controlled so that a level of the plate control signal is changed after a given time delay from a later time point among a half-cycle lapse time point of the external clock signal and a generated time point of the sense amplifier enable signal.

According to an embodiment of the present invention, a method of controlling a writing section of a synchronous FeRAM operating synchronously in relation to an external clock signal comprises applying data of a first logic state or data of a second logic state different from the first logic state, to a memory cell; and controlling a first writing section in which the data of the first logic state is written and a second writing section in which the data of the second logic state is written, in response to the external clock signal.

The first writing section and the second writing section can be discriminated by a level state of the plate control signal applied to a plate line connected to the memory cell, and a time point that is changed from the first writing section to the second writing section may be a half-cycle lapse time point of the external clock signal.

The first and second writing sections can be controlled variably, thus a stabilized write operation can be performed, and the reliability of data stored in the memory cells can be tested.

### BRIEF DESCRIPTION OF THE DRAWINGS

Exemplary embodiments of the present invention can be understood in more detail from the following descriptions taken in conjunction with the accompanying drawings, and wherein:

FIG. 1 is a hysteresis curve of a known ferroelectric material;

FIG. 2 is a circuit diagram illustrating a known memory cell of a ferroelectric memory cell array;

FIG. 3 is a timing diagram of a write operation in a known FeRAM;

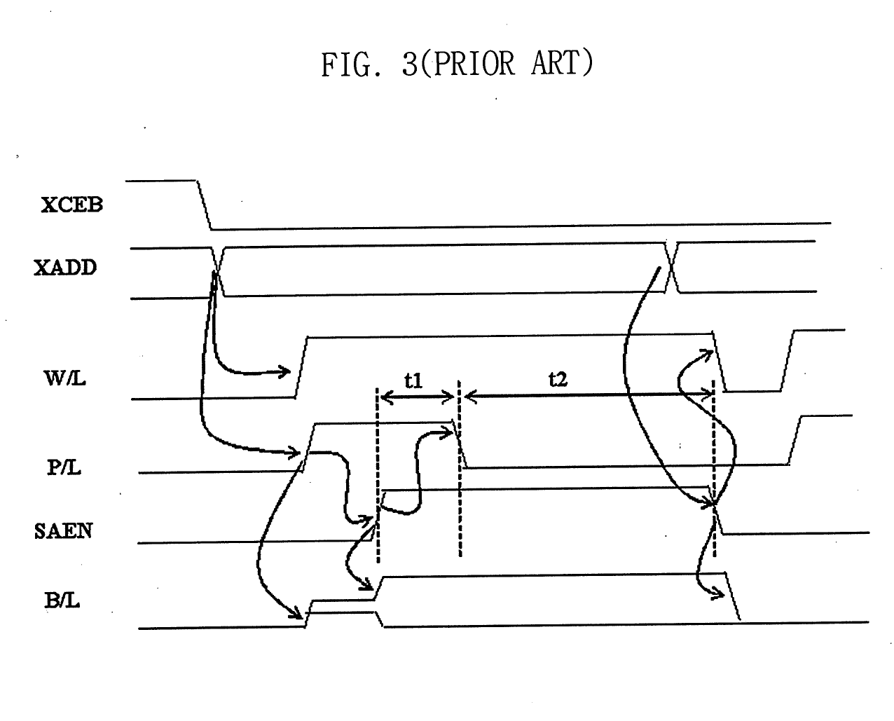

FIG. 4 is a timing diagram of a write operation in a FeRAM according to an exemplary embodiment of the present invention;

FIG. 5 is a circuit diagram of a writing control circuit for a FeRAM according to an embodiment of the present invention; and

FIG. 6 is a circuit diagram of the short pulse generator used in the circuit of FIG. 5.

### DESCRIPTION OF THE EXEMPLARY EMBODIMENTS

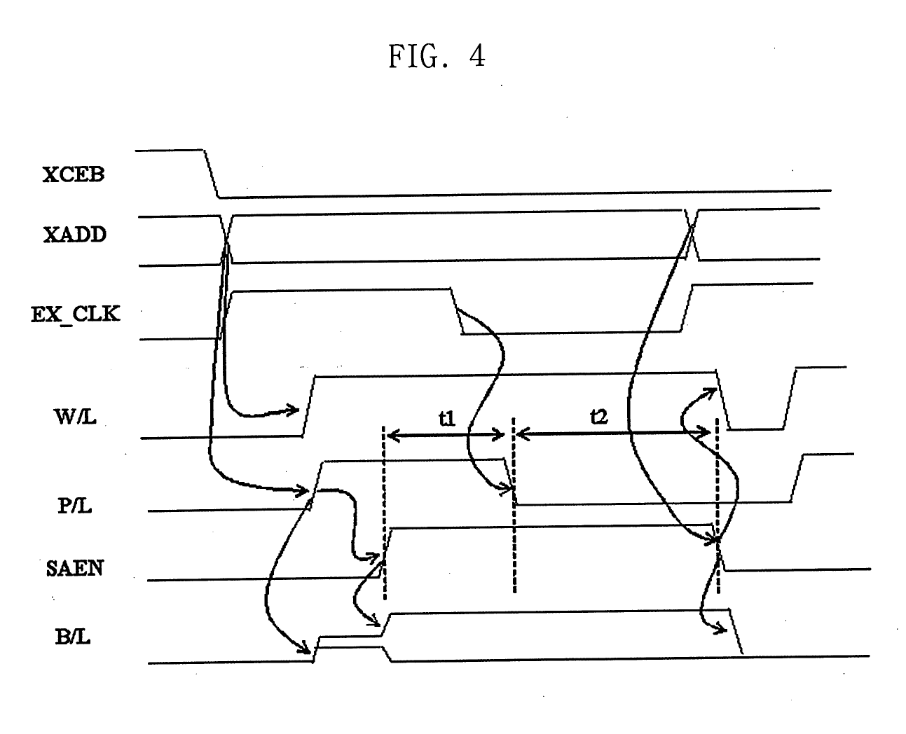

Hereinafter, exemplary embodiments of the present invention will be described in detail with reference to FIGS. 4 to 6. It will be understood by those skilled in the art that the present invention can be embodied by numerous different types and is not limited to the following described embodiments.

According to an exemplary embodiment of the invention, a ferroelectric random access memory(FeRAM) device includes a memory cell and a writing control circuit for controlling a writing section in a write operation. The configuration of the FeRAM according to an exemplary embodiment is the same as a known FeRAM, except for the writing control circuit.

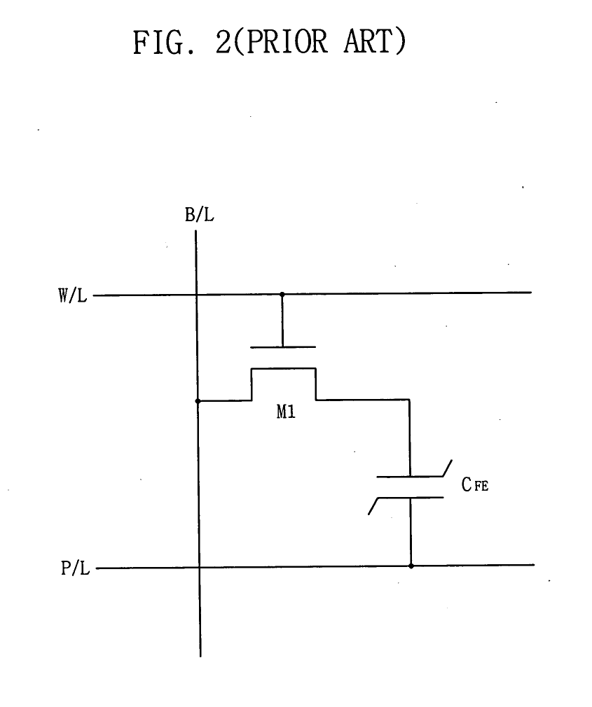

The memory cell has the configuration as shown in FIG. 2, and is constructed of one access transistor and one ferroelectric capacitor. The access transistor M1 has two terminals, a source terminal and a drain terminal, which are connected between one electrode of the ferroelectric capacitor C_{FE} and a bit line B/L, and has a gate connected to a word line W/L. One electrode of the ferroelectric capacitor C_{FE} is connected to the access transistor M1, and the other is connected to the plate line P/L.

In the following, data of a first logic state indicates data ‘0’ and data of a second logic state indicates data ‘1’. An exemplary embodiment of the invention will be described as follows, assuming that when a plate control signal applied to a plate line P/L has a level of a power source voltage, it is indicated that the plate line P/L was enabled, and that when the plate control signal has a ground level, it is indicated that the plate line P/L was disabled.

FIG. 4 is a timing diagram of a write operation in an FeRAM according to an exemplary embodiment of the present invention.

As shown in FIG. 4, while an external chip enable signal XCEB is maintained in an enable state at a low level, an address signal XADD is applied from the outside. In other words, an address toggling is generated. A specific memory cell to be written is selected in response to the address signal XADD. A word line W/L of the specific memory cell is enabled by a word line decoder and driver circuit that responds to the address signal XADD.

The plate line P/L is enabled by a plate control signal generated in a plate line driver circuit responding to the address signal XADD. When the plate line P/L is enabled, a reading section starts. When the plate line P/L is enabled and the reading section starts, a voltage corresponding to data stored in the selected memory cell is developed to a bit line B/L maintained in a ground voltage state.

Then, after the plate line P/L is enabled and a given delay lapses, a sense amplifier enable signal SAEN used to operate a sense amplifier within the FeRAM is enabled, and the sense amplifier is enabled. When the sense amplifier is enabled, the reading section is finished.

Subsequently, a data writing section is divided into a first writing section t1 of data ‘0’ having a first logic state, and a second writing section t2 of data ‘1’ having a second logic state, according to an enable or disable state of the plate line P/L. A time from an enabled time point of the sense amplifier enable signal SAEN to a disabled time point of the plate line P/L, is the first writing section t1, and a time from the disabled time point of the plate line P/L to a disabled time point of the sense amplifier enable signal SAEN, is the second writing section t2.

At the writing section t1 of data ‘0’, the write operation is generated when a state of data applied through the bit line B/L from the outside is ‘0’. In other words, when data inputted from the outside is ‘0’, the data ‘0’ is written by a voltage level difference between the bit line B/L maintaining a ground level by the applied data ‘0’ and the plate line P/L having an enable state as a level of the power source voltage.

Meanwhile, when data applied through the bit line B/L is ‘1’, a voltage of the bit line B/L maintains a level of the power source voltage, and there is no voltage difference from the plate line P/L having an enable state, thus no operation occurs. The write operation of data ‘0’ is performed after lapse of a given time following the sense amplifier enable signal SAEN being enabled, and before the plate line P/L is disabled.

The writing section of data ‘0’ is controlled by the writing control circuit constituting the FeRAM. In the writing control circuit according to a first exemplary embodiment of the invention, a disable time point of the plate line P/L deciding a writing section of data ‘0’ is controlled in response to an external clock signal EX_CLK, contrary to that in the conventional circuit. The external clock signal EX_CLK is toggled by frequency, such as by the address signal XADD. For example, the external clock signal EX_CLK is shifted from a low level to a high level at a toggling time point of the address signal XADD, and is transited from the high level to a low level after a half cycle or half period, then is again transited from the low level to a high level at a toggling time point of the address signal XADD.

In the writing control circuit, after lapse of a given delay from a time point when the external clock signal EX_CLK is shifted from a high level to a low level, the plate line P/L is disabled. In other words, the plate line P/L is controlled to be disabled after a lapse of one half-cycle of the external clock signal EX_CLK. Thus, the writing section of data ‘0’ can be controlled by the frequency of the external clock signal EX_CLK. Consequently, even though a cycle time is varied, the writing period for data ‘0’ can be guaranteed to be stable.

According to an embodiment of the present invention, in the writing control circuit, the first writing section t1 and the second writing section t2 are controlled in response to the external clock signal EX_CLK and the sense amplifier enable signal SAEN, which ensures a stabilized writing section in case a cycle time is very short, that is, in case the operating frequency is high. In other words, when a half cycle time point, present when the external clock signal EX_CLK is shifted from a high level to a low level, is earlier than an enabled time point of the sense amplifier enable signal SAEN, and so when a disable time point of the plate line P/L is controlled only by the external clock signal EX_CLK, the first writing section t1 becomes short, thus the writing of data ‘0’ may be unstable. Hence, in the writing control circuit of the FeRAM according to an embodiment of the present invention, a half-cycle lapse time point of the external clock signal EX_CLK is compared with an enable time point of the sense amplifier enable signal SAEN, and the plate line P/L is disabled after a lapse of a given delay time from a later time point among the compared time points, thus a stabilized first writing section t1 can be ensured.

When the first writing section t1 is varied, the second writing section t2, which continues from an end of the first writing section t1, is also varied. When the first writing section t1 is lengthened, the second writing section t2 automatically becomes shortened by a corresponding time length, which does not react as an impediment to ensuring a stabilized second writing section t2. This is why the second writing section t2 is always ensured by a time interval corresponding to a half cycle of the external clock signal EX_CLK, or the first writing section t1 is lengthened enough not to impede the writing of the second writing section.

The description of the timing diagram of FIG. 4 continues as follows.

The write operation of data ‘0’ is performed at the first writing section t1, then the write operation of data ‘1’ is performed at the second writing section t2 as the writing section of data ‘1’. When data applied through the bit line B/L from the outside is ‘1’, the data ‘1’ is written by a level difference between the bit line B/L maintaining a level of the power source voltage by the applied data ‘1’ and the plate line P/L having a disable state as the ground level.

Meanwhile, when data applied through the bit line B/L is ‘0’, a voltage of the bit line B/L maintains a ground level state, and there is no a voltage difference from the plate line P/L having a disable state, thus no operation occurs. The write operation of data ‘1’ continues until the sense amplifier enable signal SAEN is disabled. The sense amplifier enable signal SAEN is disabled at a time when an external address signal XADD of the next cycle is applied. Then, the bit line B/L is precharged, and the word line W/L is disabled.

The writing control circuit according to exemplary embodiments of the invention is configured to control a first writing section t1 to write data of a first logic state in the memory cell and a second writing section t2 to write data of a second logic state different from the data of the first logic state, in response to the external clock signal EX_CLK, as in the embodiment described in regard to FIG. 4. Also, as in the embodiment of the present invention described in regard to FIG. 4, the writing control circuit can be configured to control a level of the plate control signal applied to the plate line P/L connected to the memory cell in response to a first control signal and a second control signal inputted from the outside, to store data applied through the bit line B/L in the memory cell. The first control signal is an external clock signal EX_CLK, and the second control signal is a sense amplifier enable signal SAEN to enable a sense amplifier provided with the FeRAM. In an embodiment of the present invention, a disable time point of the plate line P/L is controlled only by an external clock signal EX_CLK, but in another embodiment of the invention, the disable time point of the plate line is controlled in response to the external clock signal EX_CLK and the sense amplifier enable signal SAEN.

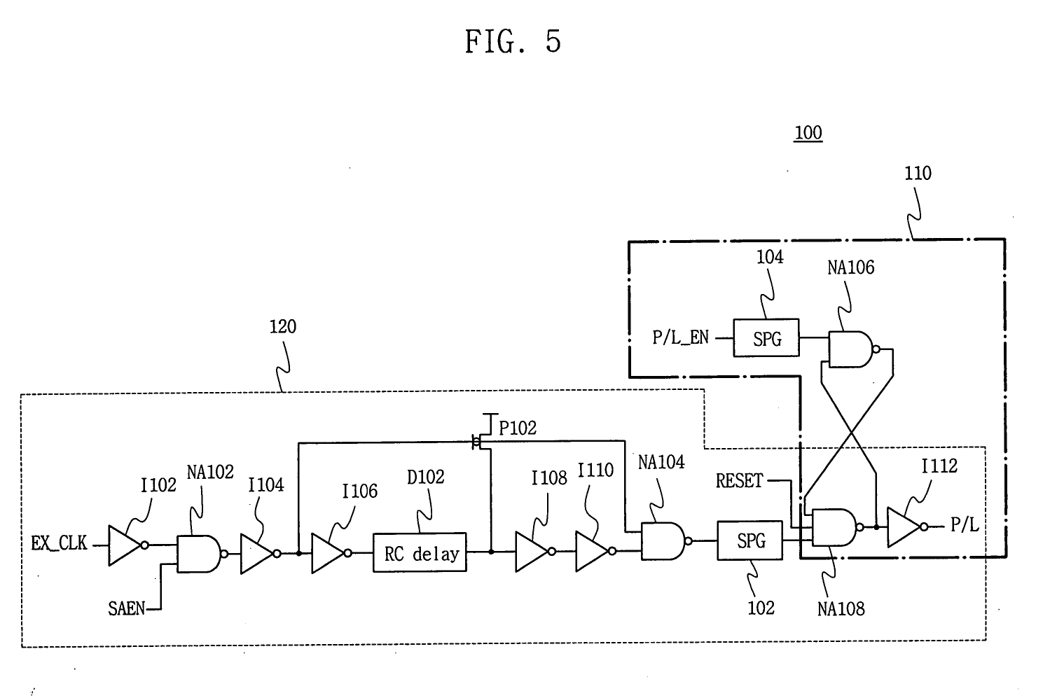

FIG. 5 illustrates a writing control circuit constituting an FeRAM according to an embodiment of the present invention. The writing control circuit constituting the FeRAM according to the embodiment can be realized by not inputting a sense amplifier enable signal SAEN in the writing control circuit of FIG. 5, thus the description therefor will be omitted from the following.

As shown in FIG. 5, a writing control circuit 100 constituting a FeRAM according to an embodiment of the present invention includes inverter circuits |102, |104, |106, |108, |110 and |112, NAND circuits NA 102, NA 104 , NA 106 a transistor P102, a delay D102, and short pulse generators (SPG) 102 and 104 connected as shown in FIG. 5.

The writing control circuit 100 has a plate line(P/L) enable path 110 and a plate line(P/L) disable path 120.

The plate line(P/L) enable path 110 is to enable the plate line P/L when an address signal XADD is applied. The plate line(P/L) disable path is to disable the enabled plate line P/L. In the plate line(P/L) disable path, the plate line P/L is disabled after a lapse of a given time delay (RC delay) from a later time point among a time point as a half-cycle time point when an external clock signal EX_CLK is shifted from a high level to a low level, and an enable time point of the sense amplifier enable signal SAEN, thereby a first writing section and a second writing section are ensured to be stable.

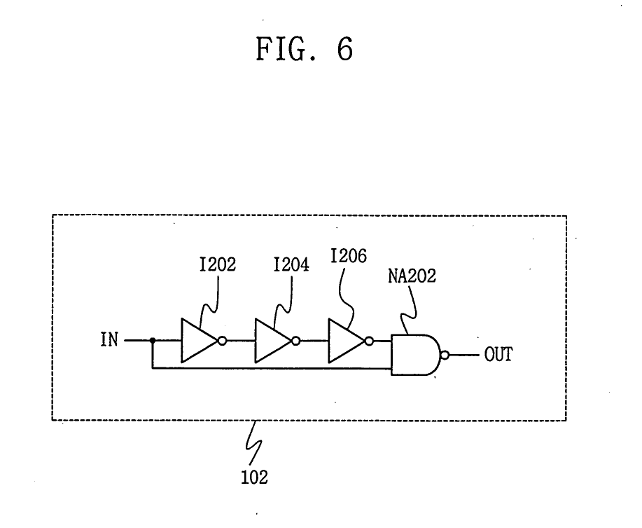

FIG. 6 illustrates the short pulse generator(SPG) shown in FIG. 5.

Referring to FIG. 6, the configuration of short pulse generators 102 and 104 used in the writing control circuit 100 of FIG. 5 is the same, thus only one short pulse generator 102 will be described as follows.

The short pulse generator 102 includes inverters 1202,1204 and 1206, and a NAND circuit Na202 connected as shown in FIG. 6. The short pulse generators 102 and 104 generate short pulse OUT in response to an applied control signal IN.

The writing control circuit 100 is provided as one example, and can be realized with the same or similar operations by those skilled in the art through various methods.

The FeRAM according to exemplary embodiments of the present invention can be applied to a synchronous FeRAM operating synchronously to the external clock signal EX_CLK. When the FeRAM according to an exemplary embodiment of the invention is an asynchronous memory device, the external clock signal EX_CLK is input through a specific test pin, through which reliability of data written in a first writing section and a second writing section can be tested. In other words, reliability of data written with controlling the first and second writing sections is tested.

As described above, the writing sections of the FeRAM are controlled only in response to an external clock signal or controlled by a sense amplifier enable signal and the external clock signal, thus a writing section of data can be varied by a cycle time, and a reliability of stored data can be tested. That is, a stabilized write operation can be performed in the FeRAM.

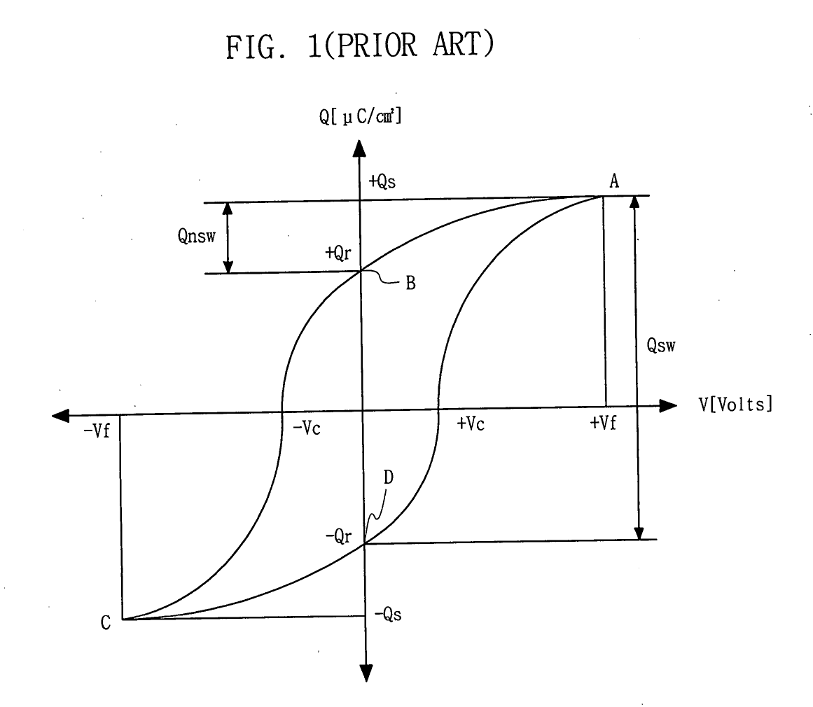

Though in the above description according to the exemplary embodiments of the invention, data ‘0’ corresponds to a state point B of the hysteresis loop shown in FIG. 1, and data ‘1’ corresponds to a state point D; the invention may have the configuration by those skilled in the art, so that data ‘1’ corresponds to a state point B of the hysteresis loop shown in FIG. 1, and data ‘0’ corresponds to a state point D. Further, the invention may have the configuration by those skilled in the art, so that the first writing section operates as a writing section of data ‘1’ and the second writing section operates as a writing section of data ‘0’.

As described above, a writing section of data is controlled only by an external clock signal or controlled variably according to a cycle time in response to an external clock signal and a sense amplifier enable signal, thus a stabilized data writing can be obtained and reliability of data stored in a memory cell can be tested.

While the present invention has been particularly shown and described with reference to exemplary embodiments thereof, it will be understood by those skilled in the art that various changes in form and details may be made therein without departing from the spirit and scope of the present invention as defined by the appended claims. For example, the internal configuration of the circuit may be changed, or internal elements of the circuit may be replaced with other equivalent elements. Accordingly, these and other changes and modifications are seen to be within the true spirit and scope of the present invention as defined by the appended claims.

What is claimed is:

1. A ferroelectric random access memory(FeRAM) device, comprising:
a memory cell constructed of one access transistor and one ferroelectric capacitor; and
a writing control circuit for controlling a first writing section to write data of a first logic state in the memory cell and a second writing section to write data of a second logic state different from the first logic state, in response to an external clock signal.

2. The FeRAM device of claim 1, wherein a time point changed from the first writing section to the second writing section is a half-cycle lapse time point of the external clock signal.

3. The FeRAM device of claim 2, wherein the access transistor of the memory cell is connected between a bit line and the ferroelectric capacitor and has a gate connected with a word line, and the ferroelectric capacitor has one end thereof coupled with the access transistor and another end coupled with a plate line.

4. The FeRAM device of claim 3, wherein the writing control circuit controls a level of a plate control signal applied to the plate line in response to the external clock signal, thereby to control the first and second writing sections.

5. The FeRAM device of claim 4, wherein the data of the first logic state is ‘0’, and the data of the second logic state is ‘1’.

6. The FeRAM device of claim 5, wherein the first writing section indicates a time wherein the plate control signal has a first level state, and the second writing section indicates a time wherein the plate control signal has a second level state different from the first level state.

7. The FeRAM device of claim 6, wherein the first level state has a level of a power source voltage, and the second level state has a ground level.

8. The FeRAM device of claim 7, wherein the FeRAM device is a synchronous ferroelectric memory device operating synchronously with the external clock signal.

9. The FeRAM device of claim 7, wherein the FeRAM device is an asynchronous semiconductor memory device, and the external clock signal is applied through a test pin.

10. A FeRAM device, comprising:
a memory cell constructed of one access transistor and one ferroelectric capacitor; and
a writing control circuit for controlling a level of a plate control signal applied to a plate line connected to the memory cell in response to first and second control signals externally inputted, thereby to write data applied through a bit line in the memory cell.

11. The FeRAM device of claim 10, wherein the first control signal is an external clock signal, and the second control signal is a sense amplifier enable signal to enable a sense amplifier provided with the FeRAM device.

12. The FeRAM device of claim 11, wherein the access transistor of the memory cell is connected between a bit line and the ferroelectric capacitor and has a gate connected with a word line, and the ferroelectric capacitor has one end thereof coupled with the access transistor and another end coupled with a plate line.

13. The FeRAM device of claim 12, wherein the FeRAM device is a synchronous FeRAM operating synchronously with the external clock signal.

14. The FeRAM device of claim 13, wherein the writing control circuit is controlled so that a level of the plate control signal is changed after a lapse of a given delay from a later time point among a half-cycle lapse time point of the external clock signal and a generated time point of the sense amplifier enable signal.

15. The FeRAM device of claim 14, wherein the plate control signal is changed from a level of a power source voltage to a ground level.

16. A method of controlling a writing section of a synchronous FeRAM operating synchronously with an external clock signal, the method comprising:
applying data of a first logic state or data of a second logic state different from the first logic state to a memory cell; and
controlling a first writing section in which the data of first logic state is written and a second writing section in which the data of second logic state is written, in response to the external clock signal.

17. The method of claim 16, wherein the first writing section and the second writing section are discriminated by a level state of a plate control signal applied to a plate line connected to the memory cell.

18. The method of claim 17, wherein a time point for changing from the first writing section to the second writing section is a half-cycle lapse time point of the external clock signal.

19. The method of claim 18, wherein the first writing section indicates a time wherein the plate control signal has a first level state, and the second writing section indicates a time wherein the plate control signal has a second level state different from the first level state.

20. The method of claim 19, wherein the first level has a level of a power source voltage, and the second level has a ground level.
